(19) United States
(12) Patent Application Publication
(10) Pub. No.: US 2005/0127517 A1
(43) Pub. Date: Jun. 16, 2005

(54) Semiconductor device

(76) Inventor: Mika Ebihara, Chiba-shi (JP)

Correspondence Address: ADAMS & WILKS, 31st Floor, 50 Broadway, New York, NY, 10004, US

(21) Appl. No.: 10/996,750

(22) Filed: Nov. 24, 2004

(30) Foreign Application Priority Data
Nov. 26, 2003 (JP) 2003-394897
Dec. 2, 2003 (JP) 2003-402788

(51) Int. Cl. H01L 21/30

(52) U.S. Cl. 257/763

(57) ABSTRACT

A PAD structure for a semiconductor device is provided. A semiconductor device includes: a polycrystalline silicon film; and an aluminum wiring which includes a barrier metal and is formed on the polycrystalline silicon film, the aluminum wiring composing a pad.

### BACKGROUND OF THE INVENTION

1. Field of the Invention

The present invention relates to a semiconductor device, and more particularly to a PAD structure in the semiconductor device.

2. Description of the Related Art

Up to now, as shown in FIG. 5, there has been known a method of forming an aluminum wiring having barrier metals on a silicon semiconductor substrate 101 through a field oxide film 102 and an intermediate insulating film 104 such as a BPSG interlayer film (For example, see JP 2003-017492 A).

However, adhesion between the BPSG interlayer film and the barrier metals is not good in a PAD having a conventional structure. Therefore, there is a problem in that PAD peeling occurs in wire bonding.

### SUMMARY OF THE INVENTION

An object of the present invention is to provide a PAD structure having a high bonding strength in which PAD peeling, which cannot be prevented in a conventional PAD structure, does not occur by a simple process without increasing the number of masks.

In order to achieve the object, the present invention includes the following characteristics.
(1) According to one aspect of the present invention, a semiconductor device includes: a polycrystalline silicon film; and an aluminum wiring which includes a barrier metal and is formed on the polycrystalline silicon film, the aluminum wiring composing a pad.
(2) In the semiconductor device, the barrier metal includes TiN.
(3) In the semiconductor device, the barrier metal includes Ti.
(4) In the semiconductor device, the barrier metal includes a laminate layer of TiN and Ti.
(5) In the semiconductor device, the aluminum wiring includes Al—Si—Cu.
(6) In the semiconductor device, the aluminum wiring includes Al—Si.
(7) According to another aspect of the present invention, the semiconductor device is made by a process including steps of:
forming a field oxide film on a surface of a semiconductor substrate; forming a polycrystalline silicon film by a CVD method and selectively patterning the polycrystalline silicon film by a photolithography method and etching; forming an interlayer film containing an impurity on an entire surface and flattening the interlayer film by heat treatment; forming a first metallic member serving as a barrier metal on an entire surface by one of vacuum evaporation and sputtering and then selectively patterning the first metallic member by a photolithography method and etching; selectively etching the interlayer film to form a contact hole on the polycrystalline silicon film; forming a second metallic member on an entire surface by one of vacuum evaporation and sputtering and then patterning the second metallic member by a photolithography method and etching; and covering an entire surface of the semiconductor substrate with a surface protective film.
(8) According to another aspect of the present invention, a semiconductor device includes: a silicon nitride film; and an aluminum wiring which includes a barrier metal and is formed on the silicon nitride film, the aluminum wiring composing a pad.
(9) In the semiconductor device, the barrier metal includes TiN.
(10) In the semiconductor device, the barrier metal includes Ti.
(11) In the semiconductor device, the barrier metal includes a laminate layer of TiN and Ti.
(12) In the semiconductor device, the aluminum wiring includes Al—Si—Cu.
(13) In the semiconductor device, the aluminum wiring includes Al—Si.
(14) According to another aspect of the present invention, a semiconductor device includes: an SiON film; and an aluminum wiring which includes a barrier metal and is formed on the SiON film, the aluminum wiring composing a pad.

As described above, according to the present invention, it is possible to provide the PAD structure having the high bonding strength in which the PAD peeling, which cannot be prevented in the conventional PAD structure, does not occur by the simple process without increasing the number of masks.

### BRIEF DESCRIPTION OF THE DRAWINGS

In the accompanying drawings:

FIG. 1 is a schematic sectional view showing a semiconductor device according to a first embodiment of the present invention;

FIG. 2 is a schematic sectional view showing a semiconductor device according to a second embodiment of the present invention;

FIGS. 3A to 3E are sectional views successively showing steps in a producing method according to the first embodiment;

FIGS. 4A to 4E are sectional views successively showing steps in a producing method according to the second embodiment; and

FIG. 5 is a final step sectional view in a conventional producing method.

### DETAILED DESCRIPTION OF THE PREFERRED EMBODIMENTS

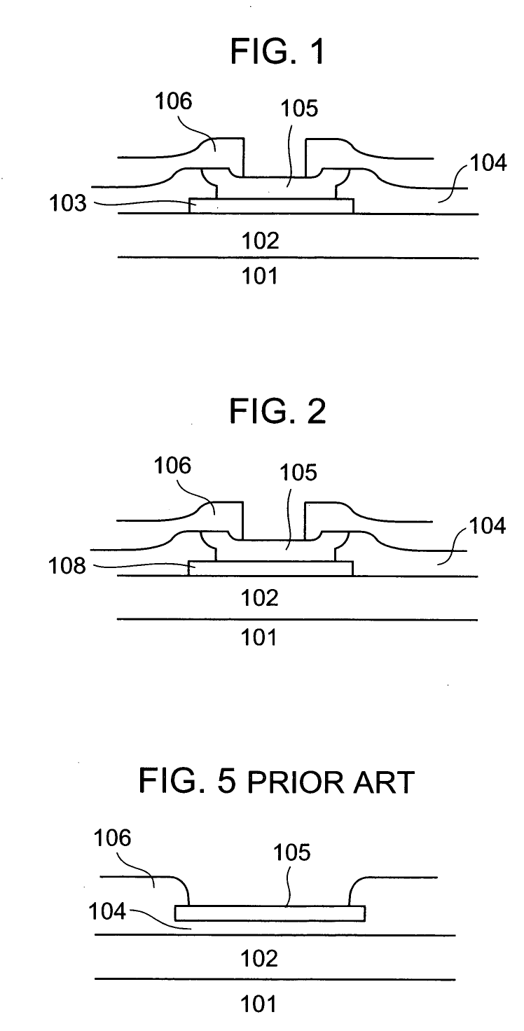

According to a semiconductor device of the present invention, a PAD structure having a high bonding strength in which PAD peeling, which cannot be prevented in a conventional PAD structure, does not occur can be provided by a simple process without increasing the number of masks. Hereinafter, preferred embodiments of the present invention will be described with reference to the accompany drawings. First, a semiconductor device according to a first embodiment of the present invention will be described in detail. FIG. 1 is a schematic sectional view showing a PAD structure in the semiconductor device according to the first embodiment of the present invention.

A field oxide film 102 is formed on a silicon semiconductor substrate 101. A laminate film which is composed of a barrier metal made of Ti and an aluminum wiring 105 is formed on the field oxide film 102 through a polycrystalline silicon film 103. The barrier metal may be TiN or a laminate film of Ti/TiN. The aluminum wiring is made of Al—Si or Al—Si—Cu.

A semiconductor device according to a second embodiment of the present invention will be described in detail. FIG. 2 is a schematic sectional view showing a PAD structure having intermediate withstanding voltage in the semiconductor device according to the second embodiment of the present invention.

The field oxide film 102 is formed on the silicon semiconductor substrate 101. A laminate film which is composed of the barrier metal made of Ti and the aluminum wiring 105 is formed on the field oxide film 102 through a silicon nitride film 108. The barrier metal may be TiN or a laminate film of Ti/TiN. The aluminum wiring is made of Al—Si or Al—Si—Cu—. Instead of using the silicon nitride film, an SiON film may bemused.

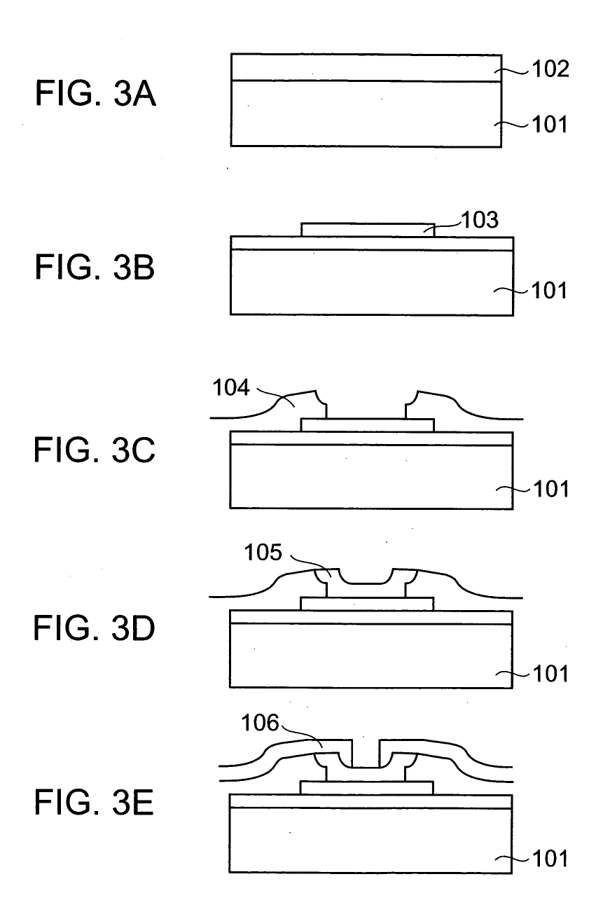

FIGS. 3A to 3E are sectional views successively showing steps in a method of producing the semiconductor device having the PAD structure according to the first embodiment of the present invention.

First, in FIG. 3A, the oxide film 102 is formed on a surface of the silicon semiconductor substrate 101. In FIG. 3B, the polycrystalline silicon film 103 is formed on the oxide film 102 by a chemical vapor deposition (CVD) method or a sputtering method. In the present invention, a polycrystalline silicon film having a thickness of 4000 angstroms is formed and set to an N-type. Phosphorus, which is an impurity element, is implanted at high concentration into the polycrystalline silicon film 103 by ion implantation or thermal diffusion using an impurity diffusion furnace. Concentration of introduced impurities, which is equal to ion implantation dosage divided by polysilicon film thickness when ion implantation is used, is set to a value equal to or larger than 2×10¹⁹ atoms/cm³. The polycrystalline silicon film is not necessarily set to the N-type. Boron, which is an impurity element, may be implanted at high concentration into the polycrystalline silicon film by ion implantation or thermal diffusion using an impurity diffusion furnace to set the polycrystalline silicon film to a P-type. After that, the polycrystalline silicon film 103 is patterned by a photolithography method and a dry etching method as shown in FIG. 3B.

In FIG. 3C, a photo resist is removed and, for example, a BPSG interlayer film 104 is formed on the entire surface. The interlayer film is formed by, for example, a CVD method and then flattened by heat treatment at 900° C. to 950° C. for 30 minutes to 2 hours. Subsequently, the interlayer film 104 is selectively etched to form a contact hole on the polycrystalline silicon film 103. According to the present invention, after dry etching, the contact hole is rounded by wet etching. After that, heat treatment is performed to activate the implanted impurity and improve the shape of contact. In the present invention, the heat treatment is performed at 800° C to 1050° C. for 3 minutes or less.

Subsequently, in FIG. 3D, the barrier metal and the aluminum wiring 105 are formed on the entire surface by vacuum evaporation, sputtering, or the like and then patterned by a photolithography method and etching to form a PAD. In this embodiment, a laminate film of TiN/Ti is used as the barrier metal and Al—Si—Cu is used for the aluminum wiring. A single layer of TiN or Ti may be used as the barrier metal and Al—Si may be used for the aluminum wiring.

Finally, in FIG. 3E, the entire substrate is covered with a surface protective film 106.

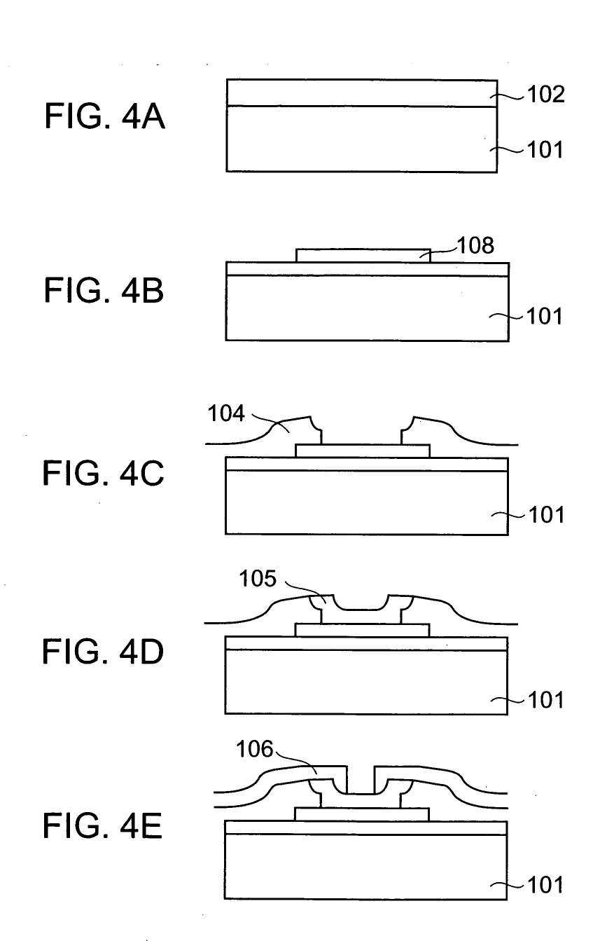

FIGS. 4A to 4E are sectional views successively showing steps in a method of producing the semiconductor device having the PAD structure according to the second embodiment of the present invention.

First, in FIG. 4A, the oxide film 102 is formed on the surface of the silicon substrate 101.

In Step-b, the silicon nitride film 108 is deposited on the oxide film 102 by a chemical vapor deposition (CVD) method or a sputtering method.

After that, the silicon nitride film 108 is patterned by a photolithography method and a dry etching method as shown in FIG. 4B.

In FIG. 4C, a photo resist is removed and, for example, a BPSG interlayer film 104 is formed on the entire surface. The interlayer film is formed by, for example, a CVD method and then flattened by heat treatment at 900° C. to 950° C. for 30 minutes to 2 hours. Subsequently, the interlayer film 104 is selectively etched to form a contact hole on the silicon nitride film 108. According to the present invention, after dry etching, the contact hole is rounded by wet etching. After that, heat treatment is performed to activate the implanted impurity and improve the shape of contact. In the present invention, the heat treatment is performed at 800° C. to 1050° C. for 3 minutes or less.

Subsequently, in FIG. 4D, the barrier metal and the aluminum wiring 105 are formed on the entire surface by vacuum evaporation, sputtering, or the like and then patterned by a photolithography method and etching to form a PAD. In this embodiment, a laminate film of TiN/Ti is used as the barrier metal and Al—Si—Cu is used for the aluminum wiring. A single layer of TiN or Ti may be used as the barrier metal and Al—Si may be used for the aluminum wiring. Instead of using the silicon nitride film, an SiON film may be used.

Finally, in FIG. 4E, the entire substrate is covered with a surface protective film 106.

1. A semiconductor device, comprising:
a polycrystalline silicon film; and
an aluminum wiring which includes a barrier metal and is formed on the polycrystalline silicon film, the aluminum wiring composing a pad.

2. A semiconductor device according to claim 1, wherein the barrier metal comprises TiN.

3. A semiconductor device according to claim 1, wherein the barrier, metal comprises Ti.

4. A semiconductor device according to claim 1, wherein the barrier metal comprises a laminate layer of TiN and Ti.

5. A semiconductor device according to claim 1, wherein the aluminum wiring comprises Al—Si—Cu.

6. A semiconductor device according to claim 1, wherein the aluminum wiring comprises Al—Si.

7. A semiconductor device according to claim 1, which is made by process comprising the steps of:
forming a field oxide film on a surface of a semiconductor substrate;
forming a polycrystalline silicon film by a CVD method and selectively patterning the polycrystalline silicon film by a photolithography method and etching;
forming an interlayer film containing an impurity on an entire surface and flattening the interlayer film by heat treatment;
forming a first metallic member serving as a barrier metal on an entire surface by one of vacuum evaporation and sputtering and then selectively patterning the first metallic member by a photolithography method and etching;
selectively etching the interlayer film to form a contact hole on the polycrystalline silicon film;
forming a second metallic member on an entire surface by one of vacuum evaporation and sputtering and then patterning the second metallic member by a photolithography method and etching; and
covering an entire surf ace of the semiconductor substrate with a surface protective film.

8. A semiconductor device, comprising:
a silicon nitride film; and
an aluminum wiring which includes a barrier metal and is formed on the silicon nitride film, the aluminum wiring composing a pad.

9. A semiconductor device according to claim 8, wherein the barrier metal comprises TiN.

10. A semiconductor device according to claim 8, wherein the barrier metal comprises Ti.

11. A semiconductor device according to claim 8, wherein the barrier metal comprises a laminate layer of TiN and Ti.

12. A semiconductor device according to claim 8, wherein the aluminum wiring comprises Al—Si—Cu.

13. A semiconductor device according to claim 8, wherein the aluminum wiring comprises Al—Si.

14. A semiconductor device, comprising:
an SiON film; and
an aluminum wiring which includes a barrier metal and is formed on the SiON film, the aluminum wiring composing a pad.

15. A semiconductor device according to claim 14, wherein the barrier metal comprises TiN.

16. A semiconductor device according to claim 14, wherein the barrier metal comprises Ti.

17. A semiconductor device according to claim 14, wherein the barrier metal comprises a laminate layer of TiN and Ti.

18. A semiconductor device according to claim 14, wherein the aluminum wiring comprises Al—Si—Cu.

19. A semiconductor device according to claim 14, wherein the aluminum wiring comprises Al—Si.
